(19) United States
(12) Patent Application Publication
(10) Pub. No.: US 2024/0413024 A1
(43) Pub. Date: Dec. 12, 2024

(54) PATTERN INSPECTION DEVICE AND PATTERN INSPECTION METHOD

(71) Applicant: Samsung Electronics Co., Ltd., Suwon-si (KR)

(72) Inventors: Sangchul YEO, Suwon-si (KR); Doyun KIM, Suwon-si (KR); Jaewon YANG, Suwon-si (KR)

(73) Assignee: Samsung Electronics Co., Ltd., Suwon-si (KR)

(21) Appl. No.: 18/532,473

(22) Filed: Dec. 7, 2023

(30) Foreign Application Priority Data
Jun. 8, 2023 (KR) 10-2023-0073740

(51) Int. Cl. H01L 21/66; G03F 1/36; G06T 7/00; G06T 7/11

(52) U.S. Cl. CPC H01L 22/24; G03F 1/36; G06T 7/0004; G06T 7/11; G06T 2207/30148

(57) ABSTRACT

Provided is a pattern inspection method including obtaining an image of a substrate on which a pattern is formed, extracting a contour based on the image, detecting positions of a target pattern based on the contour, generating pattern inspection data by performing a curve-fitting on the detected positions of the target pattern, and analyzing the pattern based on the pattern inspection data, wherein the curve-fitting is performed by using at least one of a Sigmoid function, a hyperbolic tangent function, and a Fermi-Dirac function, and wherein the pattern inspection data includes a width in a first direction, a height in a second direction, and a pattern slope of the target pattern.

### CROSS-REFERENCE TO RELATED APPLICATION

This application is based on and claims priority under 35 U.S.C. § 119 to Korean Patent Application No. 10-2023-0073740, filed on Jun. 8, 2023 in the Korean Intellectual Property office, the disclosure of which is incorporated by reference herein in its entirety.

### BACKGROUND

Various example embodiments to a pattern inspection device and/or a pattern inspection method.

In the manufacturing of semiconductor devices, it is necessary or desirable to precisely measure fine patterns formed by a photo-lithography process, an etching process such as a wet etching and/or dry etching process, etc. To identify whether the fine patterns have been formed in accurate dimensions before and after a pattern forming process, an electrical characteristics inspection and/or a measurement of critical dimensions (CDs) is performed. For example, a scanning electron microscope (SEM) is used as an equipment for measuring the CDs. However, a pattern measurement accuracy of a highly fine pattern formed by using an extreme ultra-violet (EUV) patterning technique is low. Accordingly, research on this issue has been conducted.

### SUMMARY

Various example embodiments may provide a pattern inspection device for improving an inspection accuracy of a pattern and/or a pattern inspection method.

The issues to be solved or improved upon by the technical ideas are not limited to those mentioned above, and other issues may be clearly understood by those of ordinary skill in the art from the following descriptions.

According to some example embodiments, there is provided a pattern inspection method including obtaining an image of a substrate on which a pattern is formed, extracting a contour based on the image, detecting positions of a target pattern based on the contour, generating pattern inspection data by performing a curve-fitting on the detected positions of the target pattern, and analyzing the pattern based on the pattern inspection data. The curve-fitting is performed by using at least one of a Sigmoid function, a hyperbolic tangent function, and a Fermi-Dirac function. The pattern inspection data includes a width in a first direction, a height in a second direction, and a pattern slope of the target pattern.

Alternatively or additionally according to some example embodiments, there is provided a pattern inspection method including obtaining an image of a substrate on which a pattern is formed, extracting a plurality of contours based on the image, obtaining a plurality of pattern coordinate values of the plurality of contours, extracting the plurality of target coordinate values for the target pattern among the plurality of pattern coordinate values based on a profile of the plurality of pattern coordinate values, generating pattern inspection data by performing a curve-fitting on the detected plurality of target coordinate values, and analyzing consistency of an optical proximity correction (OPC) pattern based on the pattern inspection data. The pattern inspection data includes a width in a first direction, a height in a second direction, and a pattern slope of the target pattern.

Alternatively or additionally according to some example embodiments, there is provided a pattern inspection method including obtaining an image of a substrate on which a pattern is formed, extracting a plurality of contours based on the image, obtaining a plurality of pattern coordinate values of the plurality of contours, extracting the plurality of pattern coordinate values of the target pattern among the plurality of pattern coordinate values based on a profile of the plurality of target coordinate values, generating pattern inspection data by performing a curve-fitting on the detected plurality of target coordinate values, and analyzing consistency of an optical proximity correction (OPC) pattern based on the pattern inspection data. The plurality of target coordinate values of the target pattern represent a transition region of a nanosheet. The pattern inspection data includes a width in a first direction, a height in the second direction, and a pattern slope of the target pattern. The generating of the pattern inspection data includes generating the pattern inspection data by using a curve-fitting method using at least one of a Sigmoid function, a hyperbolic tangent function, and a Fermi-Dirac function, on the plurality of target coordinate values. The extracting of the plurality of target coordinate values includes extracting pattern coordinate values of a region, where a slope changes in the profile, as the target coordinate value.

### BRIEF DESCRIPTION OF THE DRAWINGS

Various example embodiments will be more clearly understood from the following detailed description taken in conjunction with the accompanying drawings in which:

FIG. 1 is a block diagram of a pattern inspection device according to an embodiment;

FIGS. 2A and 2B are cross-sectional views of an optical proximity correction (OPC) pattern of a transition region of a nanosheet, according to some example embodiments;

FIG. 3 is a block diagram of a pattern inspection method according to some example embodiments;

FIG. 4 is a cross-sectional view of an inspection object of a pattern inspection device and a pattern inspection method, according to some example embodiments;

FIG. 5 is a cross-sectional view of a scanning electron microscope (SEM) image including a pattern in a transition region of a nanosheet, according to some example embodiments;

FIG. 6 is a graph illustrating a plurality of contours according to some example embodiments; and

FIG. 7 is a graph illustrating a pattern inspection method according to some example embodiments.

### DETAILED DESCRIPTION OF EXAMPLE EMBODIMENTS

Hereinafter, some example embodiments will be described in detail with reference to the accompanying drawings. Identical reference numerals are used for the same constituent elements in the drawings, and duplicate descriptions thereof are omitted.

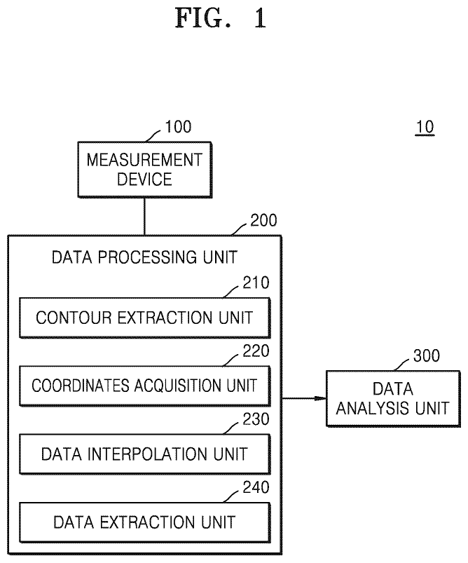

FIG. 1 is a block diagram of a pattern inspection device 10 according to some example embodiments.

Referring to FIG. 1, the pattern inspection device 10 may include a measurement device 100, a data processing unit 200, and a data analysis unit 300.

The measurement device 100 may include a stage, an electron supply unit, and an electron detection unit. A semiconductor substrate may be seated on the stage. The measurement device 100 may inspect patterns formed on a substrate. In some example embodiments, the measurement device 100 may include any one or more of an optical microscope such as a confocal microscope, an SEM, a transmission electron microscope (TEM), a focused ion beam (FIB) inspection apparatus, and an electron beam inspection apparatus. The measurement device 100 may measure the semiconductor substrate within a cleanroom; however, example embodiments are not limited thereto.

In some example embodiments the measurement device 100 may irradiate an electron beam onto the substrate via the electron supply unit. In addition, the measurement device 100 may detect secondary electrons emitted by the substrate by using the electron detection unit. The measurement device 100 may generate data of the patterns by scanning strength of the secondary electrons emitted by the patterns on the substrate. Data on the patterns may include an image such as a SEM image.

The data processing unit 200 may include a contour extraction unit 210, a coordinate acquisition unit 220, a data interpolation unit 230, and a data extraction unit 240. The data processing unit 200 may be connected to the electron supply unit and the electron detection unit of the measurement device 100. The data processing unit 200 may receive data from the measurement device 100, and store and/or process the data. In some example embodiments, the data processing unit 200 may receive an SEM image of patterns of the substrate from the measurement device 100.

The data processing unit 200 may include, for example, at least one processor. For example, the data processing unit 200 may, by executing software, control at least one other component (for example, the electron supply unit or the electron detection unit), and perform various data processing or data computation. According to some example embodiments, the data processing unit 200 may, as at least a portion of data processing or data computation, store data received from the other components (for example, the electron supply unit and/or the electron detection unit) in a volatile memory, process commands or data stored in the volatile memory, and store the resultant data in a non-volatile memory.

According to some example embodiments, the data processing unit 200 may include a main processor (for example, a central processing unit or an application processor) or an auxiliary processor operable independently or together with the main processor (for example, a graphics processing unit, a neural processing unit (NPU), an image signal processor, a sensor hub processor, or a communication processor).

According to some example embodiments, when the data processing unit 200 includes a main processor and an auxiliary processor, the auxiliary processor may be configured to use lower power than the main processor, and/or may be set to be specialized in a designated function. The auxiliary processor may be implemented separately from or as a portion of the main processor. Example embodiments are not limited thereto.

The auxiliary processor may, for example, instead of the main processor while the main processor is in an inactive (for example, sleep) state, or together with the main processor while the main processor is in an active (for example, application processing) state, control at least a portion of functions or states related with at least one component (for example, the electron supply unit and/or the electron detection unit) among the components of the measurement device 100.

According to some example embodiments, the auxiliary processor (for example, an image signal processor or a communication processor) may be implemented as a portion of other components (for example, a communication module) functionally related thereto. According to some example embodiments, the auxiliary processor (for example, a neural network processor) may include a hardware structure specialized in processing of an artificial intelligence model. The artificial intelligence model may be generated by using a machine learning. The machine learning may be performed in the data processing unit 200 itself, in which the artificial intelligence model is processed, and may also be performed by using a separate server.

The contour extraction unit 210 may receive an image such as a SEM image of the pattern from the measurement device 100. The contour extraction unit 210 may extract contour from the image of the pattern.

The coordinate acquisition unit 220 may detect a position of a target pattern. The target pattern may correspond to a transition region of a nanosheet in a semiconductor device to be described below. The coordinate acquisition unit 220 may obtain a plurality of pattern coordinate values of a plurality of contours. In addition, the coordinate acquisition unit 220 may extract the plurality of pattern coordinate values of the target pattern based on profiles or shapes of the plurality of pattern coordinate values. In some embodiments, the coordinate acquisition unit 220 may extract, as the target coordinate value, a pattern coordinate value in a region where a profile or a shape slope of the plurality of pattern coordinate values is changed. In this case, each of the pattern coordinate value and the target coordinate value may include an X-axis coordinate value and a Y-axis coordinate value.

The data interpolation unit 230 may generate interpolation data based on the target coordinate value. In some embodiments, a first piece of data may be generated by curve-fitting or interpolating a plurality of target coordinate values detected by the coordinate acquisition unit 220. In addition, the data interpolation unit 230 may generate a second piece of data by differentiating the first piece of data.

In some embodiments, the data interpolation unit 230 may extract a third piece of data by filtering the second piece of data. The data interpolation unit 230 may match the second piece of data to a sigma value of a Gaussian filter, and extract a Gaussian distribution having the matched sigma value as the third piece of data. For example, the data interpolation unit 230 may extract a Gaussian distribution having a three-sigma value as the third piece of data. In this manner, the outlier may be removed, and the matching degree of the pattern may be predicted by using the third piece of data having a higher reliability. In addition, the data interpolation unit 230 may normalize the plurality of target coordinate values. In some embodiments, the data interpolation unit 230 may normalize the plurality of target coordinate values based on the coordinates of (0.0).

The data extraction unit 240 may extract and/or generate pattern inspection data based on the first through third pieces of data. The pattern inspection data may include a width of the target pattern in a horizontal direction or a first direction, a height in a second direction or a vertical direction perpendicular to the first direction, and a pattern slope. In some example embodiments, the data extraction unit 240 may calculate the height of the pattern inspection data in the vertical direction based on the difference between the maximum and minimum values of Y-axis coordinate values of the plurality of target coordinate values.

In some embodiments, the data extraction unit 240 may calculate and/or obtain the width in the horizontal direction of the pattern inspection data based on the third piece of data. In addition, the data extraction unit 240 may calculate and/or obtain the pattern slope of the pattern inspection data by dividing the height in the vertical direction by the width in the horizontal direction.

In addition, the pattern inspection device may include a database (not illustrated). The database may transfer and/or receive data to/from the measurement device 100, the data processing unit 200, and the data analysis unit 300. The database may have a general data structure implemented in a storage space (hard disk or memory) of a computer system by using a management program.

The database may have a data storage type capable of freely searching, extracting, deleting, editing, and/or adding data. The database may be implemented by using a relationship-type database management system (RDBMS), such as one or more of Oracle, Infomix, Sybase, and DB2, an object oriented database management system (OODBMS), such as Gemston, Orion, and O2, an XML native database, such as Excelon, Tamino, and Sekaiju, and may include proper fields and/or elements to achieve its own functions. Example embodiments are not limited thereto.

In some example embodiments, the database may receive data from the measurement device 100, and store the received data. The database may store a pattern layout on the substrate, an SEM image, the first piece of data, the second piece of data, the third piece of data, and the pattern inspection data to be described, which are received from the measurement device 100.

The data analysis unit 300 may analyze consistency of an optical proximity correction (OPC) pattern with respect to the pattern based on the pattern inspection data. In some example embodiments, the data analysis unit 300 may determine the consistency of the OPC pattern of the pattern based on the width in the horizontal direction, the height in the vertical direction, and the pattern slope of the pattern inspection data. The OPC pattern may represent a recessed pattern of the transition region of the nanosheet.

Any or all of the elements described with reference to FIG. 1 may communicate with any or all other elements described with reference to FIG. 1; for example, any element may engage in one-way and/or two-way and/or broadcast communication with any or all other elements in FIG. 1, to transfer or exchange information such as but not limited to data and/or commands, in a serial and/or parallel manner, via a wireless and/or a wired bus (not illustrated).

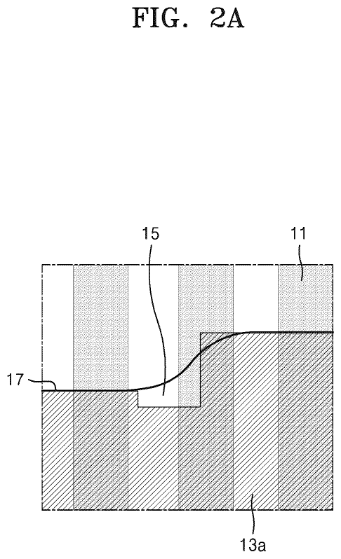

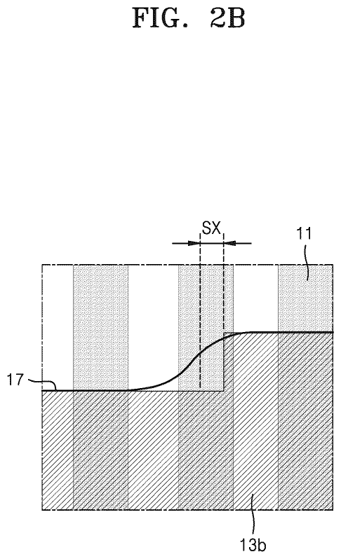

FIGS. 2A and 2B are cross-sectional views of the OPC pattern of a transition region of a nanosheet 17, according to various example embodiments.

Referring to FIGS. 2A and 2B, the pattern on the substrate subject to the inspection may include a plurality of gate lines 11, the nanosheet 17, and a source/drain region (not illustrated). FIGS. 2A and 2B illustrate plan views of a semiconductor device; example embodiments are not limited thereto.

The substrate may include a semiconductor, such as Si and/or Ge, and/or a compound semiconductor such as one or more of SiGe, SiC, GaAs, InAs, InGaAs, and InP. The terms “SiGe”, “SiC”, “GaAs”, “InAs”, “InGaAs”, and “InP” used may be referred to as materials including elements included in each term but may not be referred to as chemical formulas representing a stoichiometric relationship. The substrate may include a conductive region (not illustrated), for example, a well doped with impurities, and/or a structure doped with impurities.

Each of the plurality of gate lines 11 may include one or more of a metal, metal nitride, metal carbide, or a combination thereof. The metal may include one or more of Ti, W, Ru, Nb, Mo, Hf, Ni, Co, Pt, Yb, Tb, Dy, Er, and Pd. The metal nitride may include one or more of TiN and TaN. The metal carbide may include TiAlC.

The nanosheet 17 may include a nanosheet stack including a plurality of nanosheets. A gate dielectric layer (not illustrated) may be arranged between the nanosheet 17 and the plurality of gate lines 11. The gate dielectric layer may include a portion covering surfaces of the plurality of nanosheets and a portion covering side surfaces thereof.

The nanosheet 17 may include semiconductor layers including the same elements. In some example embodiments, the nanosheet 17 may include a Si layer. The nanosheet 17 may be doped with a dopant of the same conductivity type as the conductivity type of the source/drain region. In some embodiments, the nanosheet 17 may include an Si layer doped with an n-type dopant in a first region. In addition, the nanosheet 17 may include a Si layer doped with a p-type dopant in a second region that is different from the first region.

In some example embodiments, the first region may include an n-channel (N) metal-oxide-semiconductor (MOS) (NMOS) transistor region, and the second region may include a p-channel (P) MOS (PMOS) transistor region; however, example embodiments are not limited thereto. In this case, the source/drain region in the first region may include a Si layer doped with an n-type dopant or a SiC layer doped with a n-type dopant. In addition, the source/drain region in the second region may include a SiGe layer doped with a p-type dopant. The n-type dopant may include one or more of phosphorus (P), arsenic (As), or antimony (Sb). The p-type dopant may include boron (B) and/or gallium (Ga). In some example embodiments, either or both of the first region and the second region may be lightly counterdoped, e.g., doped with dopants of a conductivity type at a much lower concentration than that of a main dopant; example embodiments are not limited thereto.

Referring to FIG. 2A, an OPC pattern 13a for forming the nanosheet 17 may include a recessed region 15 for forming a transition region of the nanosheet 17. Referring to FIG. 2B, an OPC pattern 13b for forming the nanosheet 17 may include a region which is shifted from a target point by a first distance SX for forming the transition region of the nanosheet 17. The pattern inspection device 10 and/or the pattern inspection method of example embodiments may inspect the SEM image to determine the consistency of the OPC patterns 13a and 13b.

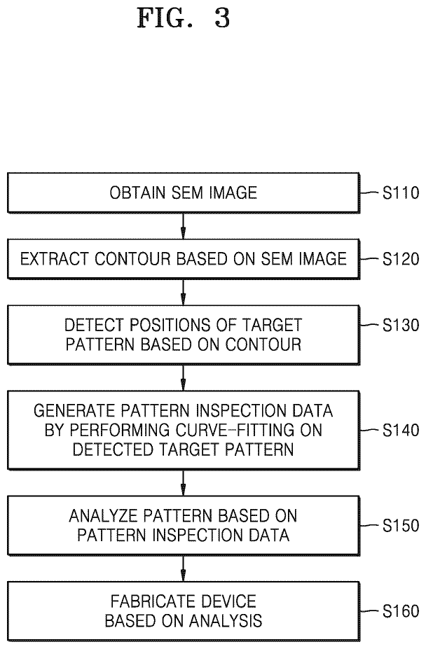

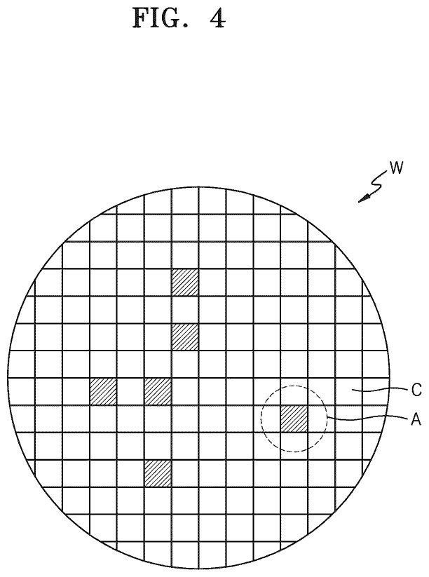

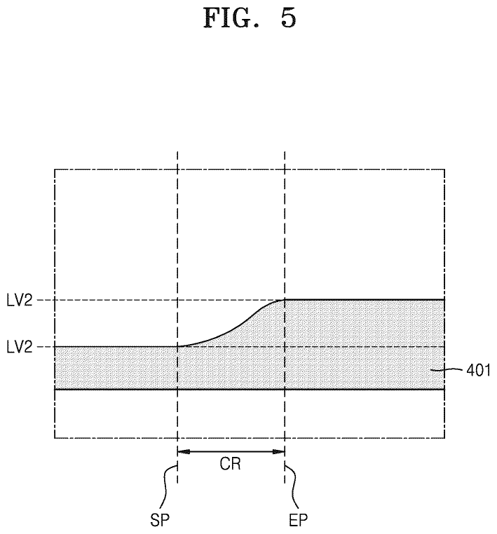

FIG. 3 is a block diagram of a pattern inspection method according to various example embodiments. FIG. 4 is a cross-sectional view of an inspection object of a pattern inspection device and a pattern inspection method, according to some example embodiments. FIG. 5 is a cross-sectional view of an SEM image including a pattern in the transition region of a nanosheet, according to some example embodiments.

Referring to FIGS. 3, 4, and 5, the pattern inspection method of example embodiments may first obtain the SEM image of the substrate in which a pattern has been formed.

In this case, the measurement device 100 may obtain a plurality of SEM images of the pattern of a substrate W (S110). The data processing unit 200 may receive the SEM image from the measurement device 100. The measurement device 100 may obtain the plurality of SEM images of a plurality of inspection regions A including the pattern of the transition region of the nanosheet in a pattern C on the substrate W. The plurality of inspection regions A may include a plurality of shot regions that are different from each other, and the measurement device 100 may obtain the plurality of SEM images of the pattern of the transition region of the nanosheet in the different shot regions. By quantitatively analyzing and processing data of a pattern in the transition region of the nanosheet in different shot regions, the pattern inspection method and the pattern inspection device of example embodiments may analyze the consistency of OPC, and at the same time, identify the tendency of defects of the pattern, and thus, may improve the reliability of a semiconductor device.

FIG. 4 illustrates a wafer W with a plurality of patterns C corresponding to chips or shots, with further inspection regions A. The number and/or the arrangement of inspection regions A, along with the number of, arrangement of, and size of patterns C are not limited to that illustrated in FIG. 4. Furthermore, a diameter of the wafer W may be 200 mm, or 300 mm, or 450 mm; example embodiments are not limited thereto.

Referring to FIGS. 4 and 5, a nanosheet 401 in the inspection region A may have heights when viewed in a plan view corresponding to vertical level heights of a first level LV1 and a second level LV2. In addition, the nanosheet 401 in the inspection region A may include a transition region CR where a height (e.g., a horizontal height) is changed from the first level LV1 to the second level LV2. In this case, the transition region CR may represent a rounded region from a first point SP, at which a height starts to change from the first level LV1, to a second point EP at which the height becomes the same as the second level LV2. In determining the consistency of the OPC pattern, an analysis on the transition region CR may be important.

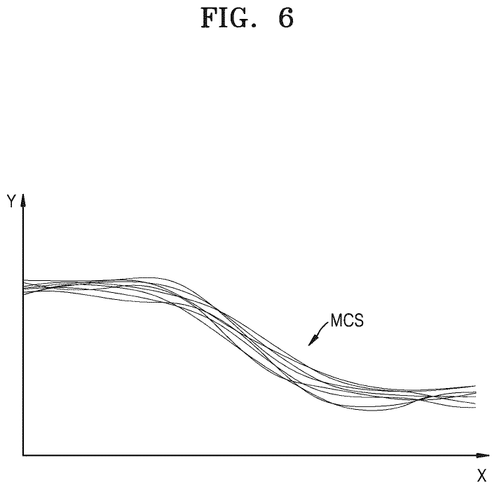

FIG. 6 is a graph illustrating a plurality of contours MCS according to some example embodiments. Below, descriptions are given with reference to FIGS. 3 through 5 together, and duplicate descriptions already given with reference to FIGS. 3 through 5 are briefly given or omitted. In FIG. 6, the X-axis may indicate a horizontal direction distance of the nanosheet 401 in FIG. 5, and the Y-axis may indicate a vertical direction distance of the nanosheet 401 in FIG. 5. In addition, a contour that inverts left and right in the horizontal direction with respect to the nanosheet 401 in FIG. 5 is illustrated.

Referring to FIGS. 1 and 3 through 6, the pattern inspection method of the example embodiments may obtain the SEM image, and then extract the plurality of contours MCS based on the SEM image (S120). Extraction of the plurality of contours MCS with respect to the SEM image may be performed by the contour extraction unit 210 of the data processing unit 200. The plurality of contours MCS may include a contour of each of a plurality of nanosheets 401 of the substrate W.

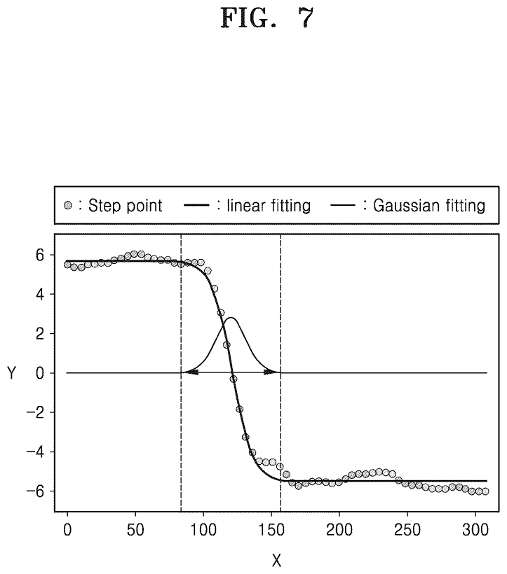

FIG. 7 is a graph illustrating the pattern inspection method according to some example embodiments. In FIG. 7, the X-axis may indicate a horizontal direction distance of the nanosheet 401 in FIG. 5, and the Y-axis may indicate a vertical direction distance of the nanosheet 401 in FIG. 5. In addition, a contour inverted left and right in the horizontal direction with respect to the nanosheet 401 in FIG. 5 is illustrated.

Referring to FIGS. 1, 3, and 7, the pattern inspection method of various example embodiments, after extracting the plurality of contours MCS, detect positions of a plurality of target patterns based on the plurality of contours MCS (S130). Detection of the positions of the plurality of target patterns may be performed by the coordinate acquisition unit 220. The positions of the plurality of target patterns and the pattern coordinate values thereof to be described below may include an X-axis coordinate value and a Y-axis coordinate value. The coordinate acquisition unit 220 may first obtain the plurality of pattern coordinate values (Step points) of the plurality of contours MCS to detect the positions of the target patterns based on the plurality of contours MCS. The plurality of pattern coordinate values (Step points) may be represented along the plurality of contours MCS at a uniform interval. The plurality of pattern coordinate values (Step points) may be obtained at one interval in a range of 1 nm to 10 nm.

In some example embodiments, the coordinate acquisition unit 220 may extract the plurality of pattern coordinate values of the target pattern based on the profile or shape of the plurality of pattern coordinate values. In some example embodiments, the coordinate acquisition unit 220 may extract, as the plurality of target coordinate values, a pattern coordinate value in a region where the profile or shape slope of the plurality of pattern coordinate values (Step points) is changed. A central region separated by dashed lines in the vertical axis on the graph may correspond to a region in which the profile or shape slope of the plurality of pattern coordinate values (Step points) changes.

Next, a pattern inspection data may be generated by curve-fitting detected positions of the target pattern (S140). In this case, the pattern inspection data may include a width in the horizontal direction of the plurality of target patterns, a height in the vertical direction thereof, and a pattern slope thereof. The curve-fitting may be performed by the data interpolation unit 230. The data interpolation unit 230 may generate interpolation data by performing a curve-fitting on the target coordinate value.

In some example embodiments, the data interpolation unit 230 may normalize the plurality of target coordinate values before performing the curve-fitting. In some example embodiments, the data interpolation unit 230 may normalize the plurality of target coordinate values based on the coordinates of (0.0).

In this case, interpolation data may represent data values, on which the curve-fitting has been performed, on the target coordinate value. The interpolation data may correspond to a thick solid line represented as a linear fitting on the graph. The data interpolation unit 230 may perform the curve-fitting by using at least one of the Sigmoid function, a hyperbolic tangent function, and the Fermi-Dirac function.

In some example embodiments, the data interpolation unit 230 may generate the first piece of data by curve-fitting or interpolating the plurality of target coordinate values detected by the coordinate acquisition unit 220. The first piece of data may be represented as a thick solid line (the linear fitting) on the graph.

Alternatively or additionally, the data interpolation unit 230 may generate the second piece of data by differentiating the first piece of data. The second piece of data may represent a slope of the first piece of data. The data interpolation unit 230 may extract the third piece of data by filtering the second piece of data. The data interpolation unit 230 may match the second piece of data to a sigma value of a Gaussian filter. Next, the data interpolation unit 230 may extract a Gaussian distribution having the matched sigma value as the third piece of data. In this case, the third piece of data may be represented as a thin solid line (Gaussian fitting) in the graph.

For example, the data interpolation unit 230 may extract a Gaussian distribution having a three-sigma value as the third piece of data. In other words, a normal distribution data in a range of 99.7% of the second piece of data may be extracted as the third piece of data. In this manner, by removing an outlier, accurate pattern data (for example, pattern inspection data) may be obtained.

In some example embodiments, after the third piece of data is extracted, the pattern inspection data may be extracted and/or generated based on the first through third pieces of data. In some example embodiments, the data extraction unit 240 may calculate the height of the pattern inspection data in the vertical direction based on the difference between the maximum and minimum values of Y-axis coordinate values of the plurality of target coordinate values.

In some example embodiments, the data extraction unit 240 may calculate and/or obtain the width in the horizontal direction of the pattern inspection data based on the third piece of data. In addition, the data extraction unit 240 may calculate and/or obtain the pattern slope of the pattern inspection data by dividing the height in the vertical direction by the width in the horizontal direction. In addition, the data extraction unit 240 may calculate the angle of the transition region of the target pattern by using the width in the horizontal direction and the height in the vertical direction.

After the pattern inspection data is generated, the pattern may be analyzed based on the pattern inspection data (S150). The analysis on the pattern may be performed by the data analysis unit 300. The data analysis unit 300 may determine the consistency of the OPC pattern based on the width in the horizontal direction, the height in the vertical direction, and the pattern slope of the pattern inspection data.

The data analysis unit 300 may determine the consistency of the OPC pattern according to whether the pattern slope exceeds a preset threshold slope. In this manner, the pattern inspection device and the pattern inspection method of example embodiments may quantitatively analyze data, such as one or more of the width, height, and slope with respect to the transition region of the nanosheet by using the SEM image. Alternatively or additionally, the pattern inspection device and/or the pattern inspection method according to various example embodiments may obtain and analyze data having an improved accuracy by using a curve-fitting, the Gaussian filter, or the like on the data. Alternatively or additionally, by analyzing data of patterns on a substrate formed from an OPC pattern, the consistency of the OPC pattern may be determined, and defects such as a leakage current occurring in the substrate may be predicted or may be more likely to be predicted and accommodated or addressed.

A semiconductor device may be fabricated based on the analysis (S160). For example, if leakage current is predicted to be large then feedforward and/or feedback mechanisms may be implemented to fabricate a semiconductor device based on the predicted leakage. Example embodiments are not limited thereto.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various example embodiments have been particularly shown and described with reference to some example embodiments thereof, it will be understood that various changes in form and details may be made therein without departing from the spirit and scope of the following claims. Furthermore, example embodiments are not necessarily mutually exclusive. For example, some example embodiments may include one or more features described with reference to one or more figures, and may also include one or more other features described with reference to one or more other figures.

What is claimed is:

1. A pattern inspection method comprising:
obtaining an image of a substrate on which a pattern is formed;
extracting a contour based on the image;
detecting positions of a target pattern based on the contour;
generating pattern inspection data by performing a curve-fitting on the detected positions of the target pattern; and
analyzing the pattern based on the pattern inspection data, wherein
the curve-fitting is performed by using at least one of a Sigmoid function, a hyperbolic tangent function, and a Fermi-Dirac function, and
the pattern inspection data comprises a width in a first direction, a height in a second direction, and a pattern slope of the target pattern.

2. The pattern inspection method of claim 1,
wherein the detecting of the positions of the target pattern based on the contour comprises:
obtaining a plurality of pattern coordinate values of the contour; and
extracting the plurality of target coordinate values of the target pattern among the plurality of pattern coordinate values based on a profile of the plurality of pattern coordinate values.

3. The pattern inspection method of claim 2, wherein
the plurality of target coordinate values of the target pattern represent a transition region of a nanosheet, and
the extracting of the plurality of target coordinate values comprises extracting pattern coordinate values of a region where a slope changes in the profile as the target coordinate values.

4. The pattern inspection method of claim 2,
wherein the generating of the pattern inspection data comprises:
calculating a height in the second direction of the pattern inspection data based on a difference between a first value corresponding to a maximum value of Y-axis coordinate values of the plurality of target coordinate values and a second value corresponding to a minimum value of the Y-axis coordinate values of the plurality of target coordinate values.

5. The pattern inspection method of claim 2, wherein the extracting of the target coordinate value further comprises normalizing the target coordinate value.

6. The pattern inspection method of claim 1,
wherein the generating of the pattern inspection data by performing a curve-fitting on the positions of the target pattern comprises:
generating a first piece of data by performing a curve-fitting on the positions of the target pattern; and
generating a second piece of data by differentiating the first piece of data.

7. The pattern inspection method of claim 6,
wherein the generating of the pattern inspection data by performing a curve-fitting on the positions of the target pattern further comprises extracting a third piece of data by filtering the second piece of data, and
wherein the extracting of the third piece of data comprises matching the second piece of data to a sigma value of a Gaussian filter, and extracting a Gaussian distribution having the matched sigma value.

8. The pattern inspection method of claim 7, wherein a width in the first direction of the pattern inspection data is calculated based on the third piece of data.

9. The pattern inspection method of claim 1,
wherein the pattern slope represents a value obtained based on dividing a height in the second direction by a width in the first direction, and
wherein the analyzing of the pattern determines consistency of an optical proximity correction (OPC) pattern based on at least one of a width in the first direction, a height in the second direction, and the pattern slope.

10. The pattern inspection method of claim 9, wherein the OPC pattern represents a recessed pattern of a transition region of a nanosheet.

11. A pattern inspection method comprising:
obtaining an image of a substrate on which a pattern is formed;
extracting a plurality of contours based on the image;
obtaining a plurality of pattern coordinate values of the plurality of contours;
extracting the plurality of target coordinate values for a target pattern among the plurality of pattern coordinate values based on a profile of the plurality of pattern coordinate values;
generating pattern inspection data by performing a curve-fitting on the detected plurality of target coordinate values; and
analyzing consistency of an optical proximity correction (OPC) pattern based on the pattern inspection data,
wherein the pattern inspection data comprises at least one of a width in a first direction, a height in a second direction, and a pattern slope of the target pattern.

12. The pattern inspection method of claim 11, wherein
the plurality of target coordinate values of the target pattern represent a transition region of a nanosheet, and
the extracting of the plurality of target coordinate values comprises extracting pattern coordinate values of a region where a slope changes in the profile as the target coordinate value.

13. The pattern inspection method of claim 11,
wherein the generating of the pattern inspection data further comprises
calculating a height in the second direction of the pattern inspection data based on the difference between a maximum value and a minimum value of Y-axis coordinate values of the plurality of target coordinate values, and
wherein the extracting of the target coordinate value further comprises normalizing the target coordinate value.

14. The pattern inspection method of claim 11,
wherein the generating of the pattern inspection data comprises:
generating the pattern inspection data on the plurality of target coordinate value by using a curve-fitting method using at least one of a Sigmoid function, a hyperbolic tangent function, and a Fermi-Dirac function.

15. The pattern inspection method of claim 11,
wherein the generating of the pattern inspection data comprises:
generating a first piece of data by performing a curve-fitting on the detected plurality of target coordinate values;
generating a second piece of data by differentiating the first piece of data; and
extracting a third piece of data by filtering the second piece of data.

16. The pattern inspection method of claim 15,
wherein extracting of the third piece of data comprises:
matching the second piece of data to a sigma value of a Gaussian filter, and extracting a Gaussian distribution having the matched sigma value as the third piece of data.

17. The pattern inspection method of claim 16, wherein
a width in the first direction of the pattern inspection data is calculated based on the third piece of data, and the pattern slope of the target pattern is calculated by dividing a height in the second direction of the pattern inspection data by a width in the first direction thereof, and
the analyzing of the pattern determines consistency of the OPC pattern based on at least one of a width in the first direction, a height in the second direction, and the pattern slope.

18. A pattern inspection method comprising:
obtaining an image of a substrate on which a pattern is formed;
extracting a plurality of contours based on the image;
obtaining a plurality of pattern coordinate values of the plurality of contours;
extracting the plurality of target coordinate values of the target pattern among the plurality of pattern coordinate values based on a profile of the plurality of pattern coordinate values;
generating pattern inspection data by performing a curve-fitting on the detected plurality of target coordinate values; and
analyzing consistency of an optical proximity correction (OPC) pattern based on the pattern inspection data, wherein
the plurality of target coordinate values of the target pattern represent a transition region of a nanosheet,
the pattern inspection data comprises a width in a first direction, a height in the second direction, and a pattern slope of the target pattern,
the generating of the pattern inspection data comprises generating the pattern inspection data by using a curve-fitting method on the plurality of target coordinate values using at least one of a Sigmoid function, a hyperbolic tangent function, and a Fermi-Dirac function, and
the extracting of the plurality of target coordinate values comprises extracting pattern coordinate values of a region where a slope changes in the profile as the target coordinate value.

19. The pattern inspection method of claim 18,
wherein the generating of the pattern inspection data comprises:
generating a first piece of data by performing a curve-fitting on the detected plurality of target coordinate values;
generating a second piece of data by differentiating the first piece of data; and
extracting a third piece of data by filtering the second piece of data, and
wherein the extracting of the third piece of data comprises:
matching the second piece of data to a sigma value of a Gaussian filter, and extracting a Gaussian distribution having the matched sigma value as the third piece of data.

20. The pattern inspection method of claim 19,
wherein the generating of the pattern inspection data comprises:
calculating a height in the second direction of the pattern inspection data based on the difference between a maximum value and a minimum value of Y-axis coordinate values of the plurality of target coordinate values,
wherein a width in the first direction of the pattern inspection data is calculated based on the third piece of data, and the pattern slope of the target pattern is calculated by dividing a height in the second direction of the pattern inspection data by a width in the first direction thereof, and
wherein the analyzing of the pattern determines consistency of the OPC pattern based on the width in the first direction, the height in the second direction, and the pattern slope.
